(19) United States
(12) Patent Application Publication
(10) Pub. No.: US 2025/0192010 A1
(43) Pub. Date: Jun. 12, 2025

(54) INTERPOSER SUBSTRATE INCLUDING OFFSET CORE LAYER

(71) Applicant: QUALCOMM Incorporated, San Diego, CA (US)

(72) Inventors: Aniket PATIL, San Diego, CA (US); Joan Rey Villarba BUOT, Escondido, CA (US); Manuel ALDRETE, Encinitas, CA (US)

(21) Appl. No.: 18/531,116

(22) Filed: Dec. 6, 2023

(51) Int. Cl. H01L 23/498; H01L 23/00; H01L 25/065

(52) U.S. Cl. CPC H01L 23/49816; H01L 23/49822; H01L 24/08; H01L 24/16; H01L 25/0657; H01L 2224/08145; H01L 2224/08235; H01L 2224/16055; H01L 2224/16235; H01L 2225/06513; H01L 2225/06517; H01L 2924/01029; H01L 2924/014; H01L 2924/1427; H01L 2924/1431; H01L 2924/1434; H01L 2924/15311

(57) ABSTRACT

In an aspect, an interposer substrate for an integrated circuit (IC) package includes a core layer, a first metallization structure on a first surface of the core layer and having an inner side facing the core layer, a second metallization structure on a second surface of the core layer and having an inner side facing the core layer, a first solder resist layer on an outer side of the first metallization structure, and a second solder resist layer on an outer side of the second metallization structure. The first metallization structure includes n metallization layer(s) in total. The second metallization structure includes m metallization layers in total. In some examples, m is greater than n.

### TECHNICAL FIELD

The present disclosure generally relates to an interposer substrate for an integrated circuit (IC) package, and more particularly, to an interposer substrate including an offset core layer having different numbers of metallization layers on respective sides of the core layer.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates or interposer substrates of the IC package. The term “substrate” in this disclosure, unless otherwise specified, refers to a packaging substrate for packaging one or more IC chips into an IC package or an interposer substrate for the IC package, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like. It will be appreciated that the specific function of the function block is more than merely a transmission of power or signals, such as performed by signal lines, traces, contacts, pads, and the like.

For example, a package on a package (POP) packaging method may correspond to vertically combining discrete logic and/or memory chips or dies to reduce the IC device size. In some examples, the POP packaging method may be used in conjunction with a molded embedded package packing method, which may be referred to as a molded embedded package on a package packaging method or a MEP packaging method. In some examples, in an IC package formed based on the POP packaging method and/or the MEP packaging method, each chip may be mounted on a respective substrate, and an interposer substrate (or also referred to as an interposer) may be used for coupling different substrates with chips mounted thereon.

In some examples, increasing the number of metallization layers of an interposer substrate for an IC package may increase the routing flexibility of the IC package and thus may enhance the functionality and/or performance of the resulting IC device. In some examples, increasing the number of metallization layers of an interposer substrate for an IC package may also increase the overall thickness of the IC package, which may affect the overall size of the electronic device incorporating the resulting IC device and thus may have a negative impact to the overall product design constraints and/or the market competitivity of the electronic device.

Accordingly, there is a need for improved interposer substrates for an IC package and methods of manufacturing the same to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an interposer substrate for an integrated circuit (IC) package includes a core layer having a first surface and a second surface; a first metallization structure on the first surface of the core layer, the first metallization structure having an inner side facing the core layer; a second metallization structure on the second surface of the core layer, the second metallization structure having an inner side facing the core layer; a first solder resist layer on an outer side of the first metallization structure; and a second solder resist layer on an outer side of the second metallization structure, wherein: the first metallization structure includes n metallization layer(s) in total, n being a positive integer equal to or greater than one, an innermost metallization layer of the first metallization structure being on the first surface of the core layer, the second metallization structure includes m metallization layers in total, m being a positive integer equal to or greater than two, an innermost metallization layer of the second metallization structure being on the second surface of the core layer, and m is greater than n.

In an aspect, a method of manufacturing an interposer substrate for integrated circuit (IC) packaging includes forming a first metallization structure on a first surface of a core layer, the first metallization structure having an inner side facing the core layer; forming a second metallization structure on a second surface of the core layer, the second metallization structure having an inner side facing the core layer; forming a first solder resist layer on an outer side of the first metallization structure; and forming a second solder resist layer on an outer side of the second metallization structure, wherein: the first metallization structure includes n metallization layer(s) in total, n being a positive integer equal to or greater than one, an innermost metallization layer of the first metallization structure being on the first surface of the core layer, the second metallization structure includes m metallization layers in total, m being a positive integer equal to or greater than two, an innermost metallization layer of the second metallization structure being on the second surface of the core layer, and m is greater than n.

In an aspect, an electronic device includes an integrated circuit (IC) package including an interposer substrate, wherein the interposer substrate comprises: a core layer having a first surface and a second surface; a first metallization structure on the first surface of the core layer, the first metallization structure having an inner side facing the core layer; a second metallization structure on the second surface of the core layer, the second metallization structure having an inner side facing the core layer; a first solder resist layer on an outer side of the first metallization structure; and a second solder resist layer on an outer side of the second metallization structure, wherein: the first metallization structure includes n metallization layer(s) in total, n being a positive integer equal to or greater than one, an innermost metallization layer of the first metallization structure being on the first surface of the core layer, the second metallization structure includes m metallization layers in total, m being a positive integer equal to or greater than two, an innermost metallization layer of the second metallization structure being on the second surface of the core layer, and m is greater than n.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a cross-sectional view of an integrated circuit (IC) package, according to aspects of the disclosure.

FIGS. 2A-2C illustrate various interposer substrate examples for an IC package, according to aspects of the disclosure.

FIGS. 3A-3D illustrate various interposer substrate examples, each having an offset core layer, for an IC package, according to aspects of the disclosure.

FIG. 3E illustrates a generalized interposer substrate example having an offset core layer for an IC package, according to aspects of the disclosure.

FIGS. 4A and 4B illustrate signal integrity eye aperture ratios based on various interposer substrate examples, according to aspects of the disclosure.

FIGS. 5A-5J illustrate structures at various stages of manufacturing an interposer substrate for an IC package, according to aspects of the disclosure.

FIG. 6 illustrates a method for manufacturing an interposer substrate for an IC package, according to aspects of the disclosure.

FIG. 7 illustrates a mobile device, according to aspects of the disclosure.

FIG. 8 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to manufacturing an interposer substrate that includes a core layer and different numbers of metallization layers on respective sides of the core layer. In some aspects, the interposer substrate may correspond to an interposer in an integrated circuit (IC) package. In some aspects, a cored interposer with an odd number of metallization layers may be formed. In some aspects, the example structures illustrated in this disclosure may be applicable to an interposer substrate as well as a packaging substrate.

Particular aspects of the subject matter described in this disclosure can be implemented to realize one or more of the following potential advantages. In some examples, the proper rigidity for an IC package may be maintained and the target signal integrity and power integrity (SIPI) performance may be achieved, while the thickness of the interposer may be well managed or reduced.

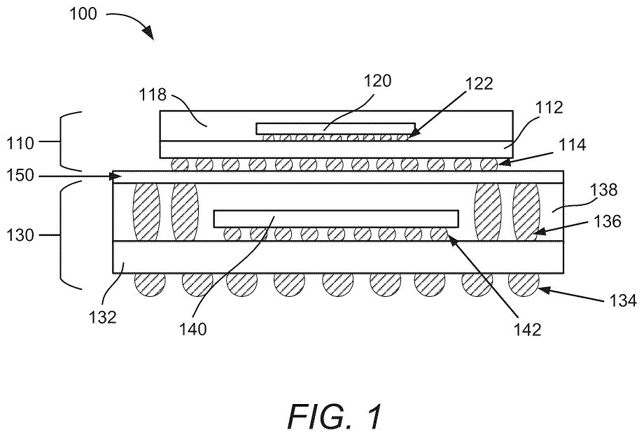

FIG. 1 is a cross-sectional view of an IC package 100, according to aspects of the disclosure. In some aspects, FIG. 1 is a simplified cross-sectional view of the IC package 100, and certain details and components of the IC package 100 may be simplified or omitted in FIG. 1.

In some aspects, as shown in FIG. 1, the IC package 100 may be based on the POP packaging method. The IC package 100 may include a first packing portion 110 over a second packing portion 130, with an interposer 150 coupling the first packing portion 110 to the second packing portion 130.

The first packing portion 110 may include a first substrate 112 (e.g., a package substrate) and first substrate terminals 114 (e.g., solder bumps or copper pillar bumps) electrically coupling the first substrate 112 and the interposer 150. In some aspects, the first substrate terminals 114 may also be configured to mechanically couple the first substrate 112 and the interposer 150. The first packing portion 110 may include a first IC chip 120 mounted on the first substrate 112 through first IC terminals 122 (e.g., solder bumps or copper pillar bumps). In some aspects, the first packing portion 110 may further include a first molding compound portion 118 disposed on the first substrate 112 and covering the first IC chip 120. In some aspects, the first molding compound portion 118 may only surround the first IC terminals 122 without covering the first IC chip 120. In some aspects, the first packing portion 110 may not include the first molding compound portion 118. In some aspects, the first IC terminals 122, the first molding compound portion 118, or both may also be configured to mechanically couple the first IC chip 120 and the first substrate 112.

The second packing portion 130 may include a second substrate 132 (e.g., another package substrate) and second substrate terminals 134 (e.g., solder bumps or copper pillar bumps) for electrically coupling the IC package 100 to an external component, such as a circuit board. The second packing portion 130 may include a second IC chip 140 mounted on the second substrate 132 through second IC terminals 142 (e.g., solder bumps or copper pillar bumps). The second packing portion 130 may include conductive structures 136 (e.g., solder bumps, copper pillar bumps, or through vias) electrically coupling the second substrate 132 and the interposer 150. In some aspects, the second packing portion 130 may further include a second molding compound portion 138 disposed on the second substrate 132 and covering the second IC chip 140. In some aspects, the second molding compound portion 138 may surround the conductive structures 136. In some aspects, the second molding compound portion 138 may only surround the second IC terminals 142 without covering the second IC chip 140 and/or without surrounding the conductive structures 136. In some aspects, the second packing portion 130 may not include the second molding compound portion 138.

In some aspects, the second IC terminals 142, the second molding compound portion 138, or both may also be configured to mechanically couple the second IC chip 140 and the second substrate 132. In some aspects, the conductive structures 136, the second molding compound portion 138, or both may also be configured to mechanically couple the second substrate 132 and the interposer 150.

As used herein, the interposer 150 is configured to electrically couple the substrates 112 and 132 and in some aspects coupling the IC chips 120 and 140 through the substrates 112 and 132 and optionally additional components (e.g., other IC chips, active components such as discrete transistors or Op Amps, and/or passive components such as resistors, capacitors, and/or inductors) formed on or embedded in the substrate 112 and/or the substrate 132.

It will be appreciated that the illustrated configuration and descriptions provided herein are merely to aid in the explanation of the various aspects disclosed herein. Accordingly, the forgoing illustrative examples should not be construed to limit the various aspects disclosed and claimed herein.

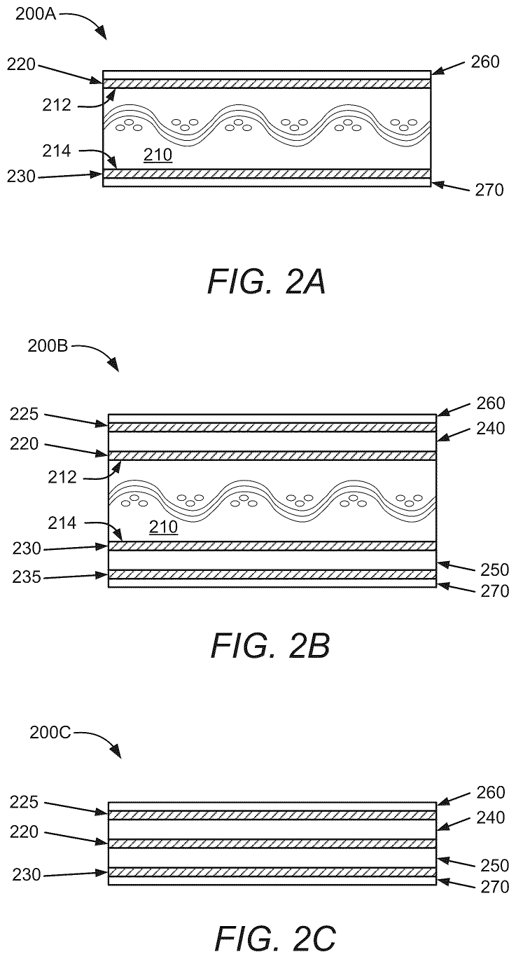

FIG. 2A illustrates an interposer substrate example 200A for an IC package, according to aspects of the disclosure. In some aspects, the interposer 150 in FIG. 1 may be based on the interposer substrate example 200A. As shown in FIG. 2A, the interposer substrate example 200A may include a core layer 210, a first metallization layer 220 on a first surface 212 of the core layer 210, a second metallization layer 230 on a second surface 214 of the core layer 210, a first solder resist layer 260 on the first metallization layer 220, and a second solder resist layer 270 on the second metallization layer 230. In some aspects, the interposer substrate example 200A may be manufactured based on a two-layer modified semi-additive process (2L-mSAP). In some aspects, the core layer 210 may include a dielectric material with reinforcement components (e.g., fiber glass sheets) embedded therein. In some aspects, the first metallization layer 220 and the second metallization layer 230 may include a conductive material, such as copper.

In some aspects, the interposer substrate example 200A depicted in FIG. 2A may correspond to only a portion of an interposer (such as the interposer 150), and certain details may be simplified or omitted in FIG. 2A. For example, the first metallization layer 220 and the second metallization layer 230 may include conductive patterns forming trace structures and/or pad structures. In some aspects, the core layer 210 may include one or more via structures formed therein, which may be configured to connect one or more pad structure of the first metallization layer 220 to respective one or more pad structure of the second metallization layer 230. In some aspects, the first solder resist layer 260 and the second solder resist layer 270 may extend to the gaps between the trace structures and the pad structures and may include openings exposing at least a portion of the pad structures of the first metallization layer 220 and the second metallization layer 230, from which one or more terminal structures (such as solder bumps or copper pillar bumps) may be formed.

In some aspects, for an IC package that includes memory chips based on a low-power double data rate (LPDDR) synchronous dynamic random-access memory (SDRAM), generation 6, standard (also referred to as LPDDR6), the operation clock rate could be equal to or greater than 5.1 GHz. In some configurations, for LPDDR6, the IC package may be based on the MEP packaging method using a three-layer embedded trace substrate (3L-ETS) and the 2L-mSAP. In some aspects, the 2L-mSAP interposer has been the bottleneck for the SIPI performance for double data rate (DDR) memory interconnections according to the study of memory chips based on a LPDDR SDRAM, generation 5X or 5T, standard (also referred to as LPDDR5X/T). In some aspects, increasing the number of layers of the interposer may improve the SIPI performance to the target set forth by LPDDR6.

FIG. 2B illustrates an interposer substrate example 200B for an IC package, according to aspects of the disclosure. In some aspects, the interposer 150 in FIG. 1 may be based on the interposer substrate example 200B. In some aspects, the components in FIG. 2B that are the same or similar to those in FIG. 2A may be given the same reference numbers, and detailed description thereof may be omitted.

As shown in FIG. 2B, the interposer substrate example 200B may include a core layer 210, a first metallization layer 220 on a first surface 212 of the core layer 210, and a second metallization layer 230 on a second surface 214 of the core layer 210. The interposer substrate example 200B may include a third metallization layer 225 and a first dielectric layer 240 between the third metallization layer 225 and the first metallization layer 220; and may include a fourth metallization layer 235 and a second dielectric layer 250 between the fourth metallization layer 235 and the second metallization layer 230. Moreover, the interposer substrate example 200B may further include a first solder resist layer 260 on the third metallization layer 225, and a second solder resist layer 270 on the fourth metallization layer 235. In some aspects, the interposer substrate example 200B may be manufactured based on a four-layer modified semi-additive process (4L-mSAP). In some aspects, the first dielectric layer 240 and the second dielectric layer 250 may include a dielectric material with pre-impregnated reinforcement components embedded therein. Also, the interposer substrate example 200B depicted in FIG. 2B may correspond to only a portion of an interposer (such as the interposer 150), and certain details may be simplified or omitted in FIG. 2B.

In some aspects, when the core layer 210 is needed for an interposer substrate, the metallization layers may be added to both the upper side and the lower side of the core layer to form a substrate structure having an even number of metallization layers, such as a two-metallization-layer structure (e.g., the interposer substrate example 200A), a four-metallization-layer structure (e.g., the interposer substrate example 200B), or a six-metallization-layer structure. In some aspects, a four-metallization-layer structure may be sufficient for achieving the target SIPI performance for LPDDR6. However, the thickness of the four-metallization-layer structure may be too large for the desirable design constraints or market acceptance of a resulting electronic device incorporating the IC package with such interposer.

FIG. 2C illustrates an interposer substrate example 200C for an IC package, according to aspects of the disclosure. In some aspects, the interposer 150 in FIG. 1 may be based on the interposer substrate example 200C. In some aspects, the components in FIG. 2C that are the same or similar to those in FIG. 2A or FIG. 2B may be given the same reference numbers, and detailed description thereof may be omitted.

As shown in FIG. 2C, the interposer substrate example 200C may include a first metallization layer 220, a second metallization layer 230, and a third metallization layer 225, without the core layer 210 as shown in FIGS. 2A and 2B. The interposer substrate example 200C may include a first dielectric layer 240 between the first metallization layer 220 and the third metallization layer 225, and a second dielectric layer 250 between the first metallization layer 220 and the second metallization layer 230. In some aspects, the interposer substrate example 200C may be referred to as having a three-layer coreless structure. Also, the interposer substrate example 200C depicted in FIG. 2C may correspond to only a portion of an interposer (such as the interposer 150), and certain details may be simplified or omitted in FIG. 2C.

In some aspects, while an interposer having three metallization layers may also be sufficient for achieving the target SIPI performance for LPDDR6, the coreless configuration may not be sufficient to maintain proper rigidity for an IC package based on a MEP packaging method.

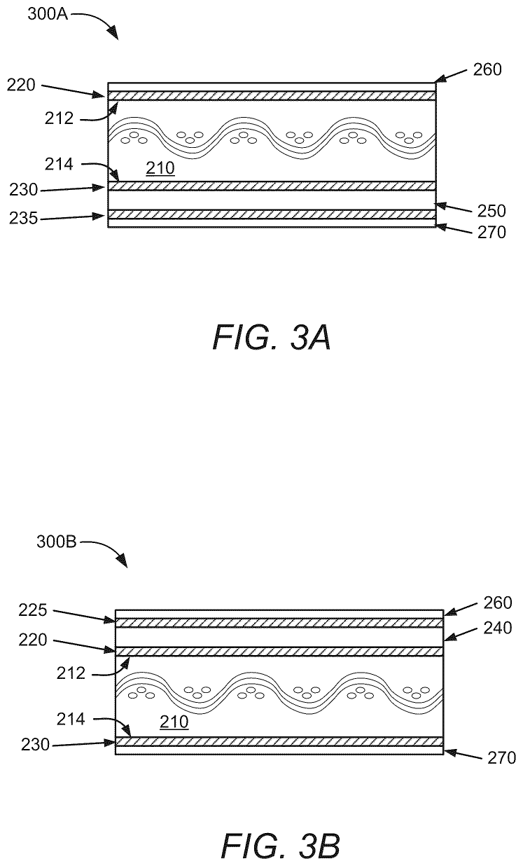

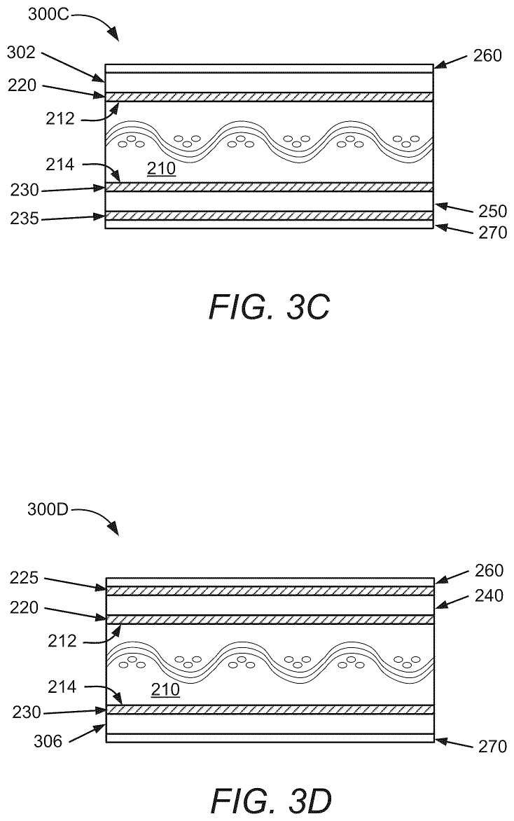

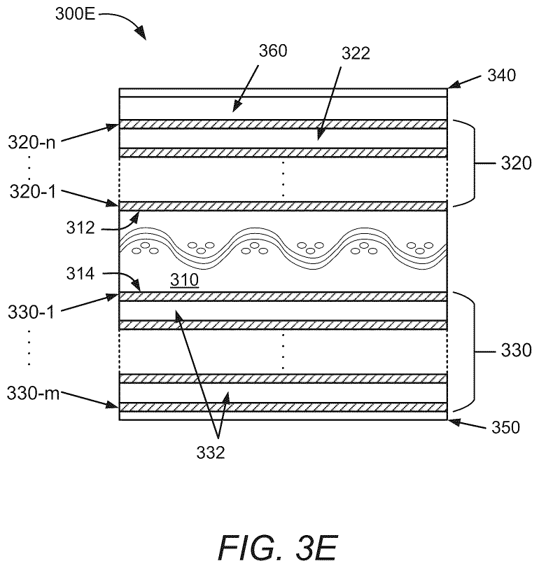

FIG. 3A illustrates an interposer substrate example 300A having an offset core layer for an IC package, according to aspects of the disclosure. In some aspects, the interposer 150 in FIG. 1 may be based on the interposer substrate example 300A. In some aspects, the components in FIG. 3A that are the same or similar to those in FIG. 2A or FIG. 2B may be given the same reference numbers, and detailed description thereof may be omitted.

As shown in FIG. 3A, compared with the interposer substrate example 200B, the interposer substrate example 300A has one metallization layer 220 over the core layer 210 and two metallization layers 230 and 235 under the core layer 210. In some aspects, the interposer substrate example 300A may correspond to an interposer substrate including an offset core layer, as a number of metallization layers over the core layer 210 is different from a number of metallization layers under the core layer 210. In some aspects, the definition regarding “over” or “under” in this disclosure may correspond to an orientation of the IC package (e.g., the IC package 100), where the side of the IC package to be mounted on a circuit board may correspond to the direction of “under,” and the opposing side of the IC package may correspond to the direction of “over.”

In some aspects, the first metallization layer 220 and the second metallization layer 230 may include conductive patterns forming trace structures and/or pad structures. In some aspects, the core layer 210 may include one or more via structures formed therein, which may be configured to connect one or more pad structure of the first metallization layer 220 to respective one or more pad structure of the second metallization layer 230. In some aspects, the first solder resist layer 260 and the second solder resist layer 270 may extend to the gaps between the trace structures and the pad structures and may include openings exposing at least a portion of the pad structures of the first second metallization layer 220 and the second metallization layer 230, from which one or more terminal structures such as solder bumps or copper pillar bumps may be formed.

In some aspects, the three metallization layers 220, 225, and 230 may be sufficient for achieving the target SIPI performance for LPDDR6. In some aspects, the core layer 210 may provide mechanical strength for maintaining proper rigidity for an IC package. Also, compared with the interposer substrate example 200B, having one less metallization layer (e.g., omitting the metallization layer 225) may correspond to a reduced thickness of the resulting interposer based on the interposer substrate example 300A.

In some aspects, the metallization layer 220 may be referred to as the metal-3 layer or the M3 layer of the resulting interposer, which may be configured to carry a first supply power or a first signal of the IC package. In some aspects, the metallization layer 230 may be referred to as the metal-2 layer or the M2 layer of the resulting interposer, which may be configured to carry a second supply power or a ground level (e.g., for power or signal returning paths and/or shielding) of the IC package. In some aspects, the metallization layer 235 may be referred to as the metal-1 layer or the M1 layer of the resulting interposer, which may be configured to carry the first supply power or a second signal of the IC package.

Moreover, FIGS. 3B-3D illustrate additional interposer substrate examples 300B, 300C, and 300D, which may be variations of the interposer substrate examples 300A.

FIG. 3B illustrates an interposer substrate example 300B having an offset core layer for an IC package, according to aspects of the disclosure. In some aspects, the interposer 150 in FIG. 1 may be based on the interposer substrate example 300B. In some aspects, the components in FIG. 3B that are the same or similar to those in FIG. 2A or FIG. 2B may be given the same reference numbers, and detailed description thereof may be omitted. As shown in FIG. 3B, compared with the interposer substrate example 200B, the interposer substrate example 300B has two metallization layers 220 and 225 over the core layer 210 and one metallization layer 230 under the core layer 210. In some aspects, the interposer substrate example 300A may correspond to an up-side-down variation of the interposer substrate example 300A.

In some aspects, the metallization layer 230 on one side of the core layer 210 may be configured to carry a first signal or a first supply power of an IC package, and the metallization layers 220 and 225 on the other side of the core layer 210 may be configured to carry a second signal, a second supply power, and/or a ground level (e.g., for power or signal returning paths and/or shielding) of the IC package. The configurations of the patterns of the metallization layers may vary based on different implementations and applications.

FIG. 3C illustrates an interposer substrate example 300C having an offset core layer for an IC package, according to aspects of the disclosure. In some aspects, the interposer 150 in FIG. 1 may be based on the interposer substrate example 300C. In some aspects, the components in FIG. 3C that are the same or similar to those in FIG. 3A may be given the same reference numbers, and detailed description thereof may be omitted. As shown in FIG. 3C, compared with the interposer substrate example 300A, the interposer substrate example 300C has an outer dielectric layer 302 between the metallization layer 220 and the solder resist layer 260. In some aspects, the outer dielectric layer 302 may include a dielectric material and may be free from having glass fibers.

FIG. 3D illustrates an interposer substrate example 300D having an offset core layer for an IC package, according to aspects of the disclosure. In some aspects, the interposer 150 in FIG. 1 may be based on the interposer substrate example 300D. In some aspects, the components in FIG. 3D that are the same or similar to those in FIG. 3B may be given the same reference numbers, and detailed description thereof may be omitted. As shown in FIG. 3D, compared with the interposer substrate example 300B, the interposer substrate example 300D has an outer dielectric layer 306 between the metallization layer 230 and the solder resist layer 270. In some aspects, the outer dielectric layer 306 may include a dielectric material and may be free from having glass fibers. In some aspects, the interposer substrate example 300D may correspond to an up-side-down variation of the interposer substrate example 300C.

FIG. 3E illustrates a generalized interposer substrate example 300E having an offset core layer for an IC package, according to aspects of the disclosure. In some aspects, the interposer substrate example 300A and interposer substrate example 300C may be illustrated based on the generalized interposer substrate example 300E depicted in FIG. 3E; and the interposer substrate example 300B and interposer substrate example 300D may be illustrated based on flipping the generalized interposer substrate example 300E depicted in FIG. 3E up-side-down.

As shown in FIG. 3E, the generalized interposer substrate example 300E may include a core layer 310, which may correspond to the core layer 210. The core layer 310 may include a first surface 312 and a second surface 314. The generalized interposer substrate example 300E may include a first metallization structure 320 on the first surface 312 of the core layer 310. In some aspects, the first metallization structure 320 may have an inner side facing the core layer 310. The generalized interposer substrate example 300E may include a second metallization structure 330 on the second surface 314 of the core layer 310. In some aspects, the second metallization structure 330 may have an inner side facing the core layer 310.

In some aspects, the first metallization structure 320 may include n metallization layer(s) in total (e.g., metallization layers 320-1 . . . 320-n), where n may be a positive integer equal to or greater than one (n≥1). In some aspects, an innermost metallization layer 320-1 of the first metallization structure 320 may be on the first surface 312 of the core layer 310. In some aspects, the second metallization structure 330 may include m metallization layers in total (e.g., metallization layers 330-1 . . . 320-m), where m may be a positive integer equal to or greater than two (m≥1). In some aspects, an innermost metallization layer 330-1 of the second metallization structure 330 may be on the second surface 314 of the core layer 310.

In some aspects, m is greater than n (m≥n). In some aspects, based on n being greater than one (e.g., when n>1), the first metallization structure 320 may further include (n−1) dielectric layers (e.g., the dielectric layer 322) disposed between respective pairs of adjacent metallization layers of the first metallization structure 320. In some aspects, the second metallization structure 330 may further include (m−1) dielectric layers (e.g., the dielectric layers 332) disposed between respective pairs of adjacent metallization layers of the second metallization structure 330.

In some aspects, the generalized interposer substrate example 300E may include a first solder resist layer 340 on an outer side of the first metallization structure 320 and a second solder resist layer 350 on an outer side of the second metallization structure 330. In some aspects, the generalized interposer substrate example 300E may further include an outer dielectric layer 360 disposed between the first metallization structure 320 and the first solder resist layer 340. In some aspects, the outer dielectric layer 360 may be omitted.

In some aspects, the interposer substrate example 300A may be illustrated based on the generalized interposer substrate example 300E with n=1, m=2, and the outer dielectric layer 360 omitted. Accordingly, the interposer substrate example 300A may correspond to the first metallization structure 320 having a first metallization layer (e.g., the metallization layer 220) that is the innermost metallization layer of the first metallization structure 320; the second metallization structure 330 having a second metallization layer (e.g., the metallization layer 230) that is the innermost metallization layer of the second metallization structure 330; and the second metallization structure further having a third metallization layer (e.g., the metallization layer 235) and a dielectric layer (e.g., the dielectric layer 250) between the second metallization layer and the third metallization layer.

In some aspects, the interposer substrate example 300B may be illustrated based on the generalized interposer substrate example 300E disposed up-side-down with n=1, m=2, and the outer dielectric layer 360 omitted. Accordingly, the interposer substrate example 300B may correspond to the first metallization structure 320 having a first metallization layer (e.g., the metallization layer 230) that is the innermost metallization layer of the first metallization structure 320; the second metallization structure 330 having a second metallization layer (e.g., the metallization layer 220) that is the innermost metallization layer of the second metallization structure 330; and the second metallization structure further having a third metallization layer (e.g., the metallization layer 225) and a dielectric layer (e.g., the dielectric layer 240) between the second metallization layer and the third metallization layer.

In some aspects, the interposer substrate example 300C may be illustrated based on the generalized interposer substrate example 300E with n=1 and m=2. Accordingly, the interposer substrate example 300C may correspond to the first metallization structure 320 having a first metallization layer (e.g., the metallization layer 220) that is the innermost metallization layer of the first metallization structure 320; the second metallization structure 330 having a second metallization layer (e.g., the metallization layer 230) that is the innermost metallization layer of the second metallization structure 330; and the second metallization structure further having a third metallization layer (e.g., the metallization layer 235) and a dielectric layer (e.g., the dielectric layer 250) between the second metallization layer and the third metallization layer. The interposer substrate example 300C may further include an outer dielectric layer (e.g., the outer dielectric layer 302) between the first metallization layer and a first solder resist layer (e.g., the solder resist layer 260).

In some aspects, the interposer substrate example 300D may be illustrated based on the generalized interposer substrate example 300E disposed up-side-down with n=1 and m=2. Accordingly, the interposer substrate example 300D may correspond to the first metallization structure 320 having a first metallization layer (e.g., the metallization layer 230) that is the innermost metallization layer of the first metallization structure 320; the second metallization structure 330 having a second metallization layer (e.g., the metallization layer 220) that is the innermost metallization layer of the second metallization structure 330; and the second metallization structure further having a third metallization layer (e.g., the metallization layer 225) and a dielectric layer (e.g., the dielectric layer 240) between the second metallization layer and the third metallization layer. The interposer substrate example 300D may further include an outer dielectric layer (e.g., the outer dielectric layer 306) between the first metallization layer and a first solder resist layer (e.g., the solder resist layer 270).

In some aspects, an interposer (such as the interposer 150) of an IC package may be formed based on any of the interposer substrate example 300A, 300B, 300C, 300D, or any interposer substrate representable based on the generalized interposer substrate example 300E. In some aspects, a first IC may be disposed over and electrically connected to the first metallization structure 320, and a second IC may be disposed under and electrically connected to the second metallization structure 330.

In some aspects, the core layer 310 may have a thickness ranging from 40 micrometers (μm) to 1000 μm. In some aspects, each one of the dielectric layers 322 and 332 of the first metallization structure 320 and of the second metallization structure 330 may have a thickness ranging from 20 μm to 70 μm. In some aspects, each one of the dielectric layers of the first metallization structure 320 and of the second metallization structure 330 comprises a dielectric material with pre-impregnated reinforcement components embedded therein. In some aspects, the outer dielectric layer 360 may be free from having glass fibers.

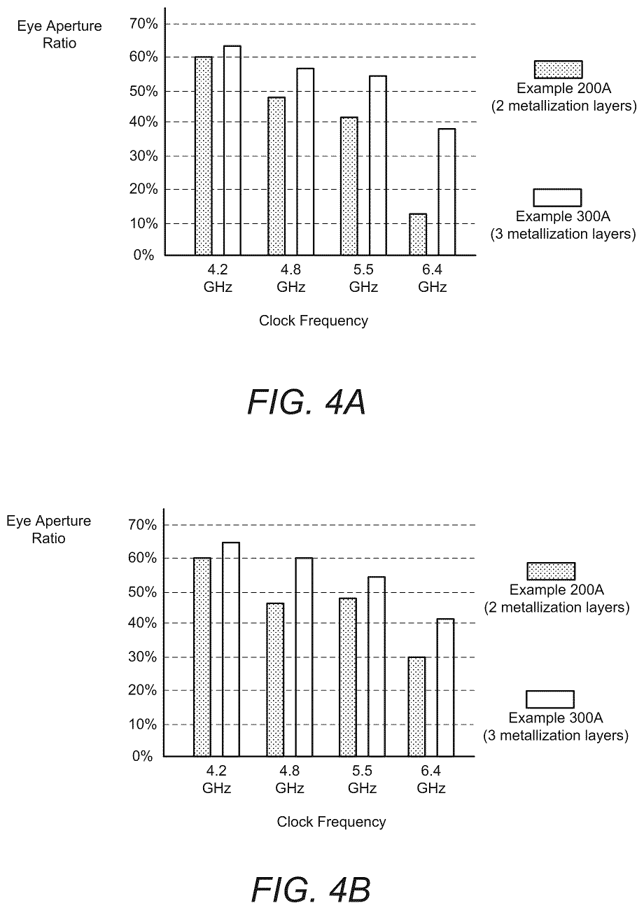

FIG. 4A illustrates signal integrity eye aperture ratios based on the interposer substrate example 200A and the interposer substrate example 300A for an IC package for LPDDR5X, according to aspects of the disclosure. FIG. 4B illustrates signal integrity eye aperture ratios based on the interposer substrate example 200A and the interposer substrate example 300A for an IC package for LPDDR6, according to aspects of the disclosure. In some aspects, the horizontal axis in FIGS. 4A and 4B represents the clock frequency of the memory chip mounted on an interposer based on the interposer substrate example 200A or the interposer substrate example 300A, and the vertical axis in FIGS. 4A and 4B represents the corresponding eye aperture ratio. In some aspects, the greater the eye aperture ratio, the better the signal integrity performance.

As shown in FIGS. 4A and 4B, the interposer with three metallization layers may have significantly improved signal integrity performance over the interposer with two metallization layers. At the same time, the core layer of the interposer substrate example 300A may provide mechanical strength for maintaining sufficient rigidity for an IC package compared with the interposer substrate example 200C. In some aspects, the time and cost for manufacturing the interposer substrate example 300A may be reduced than that for the interposer substrate example 200C.

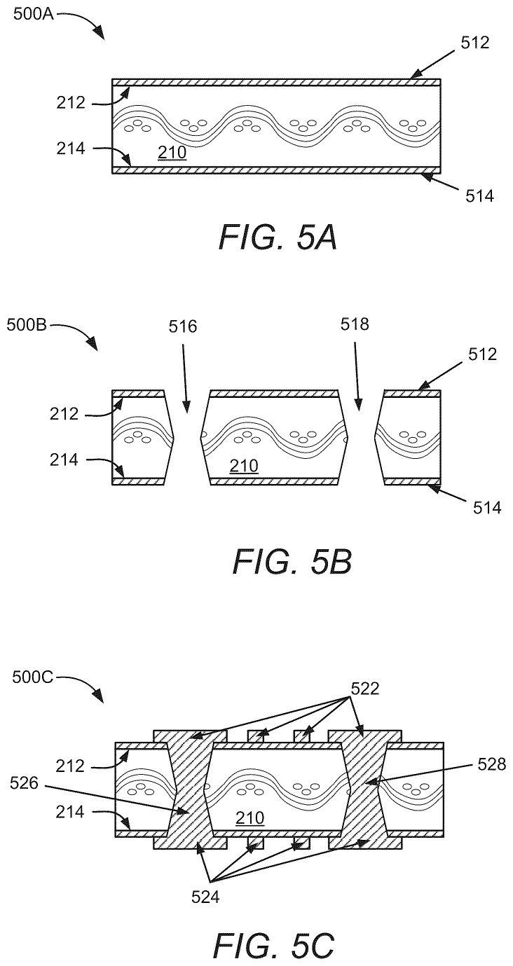

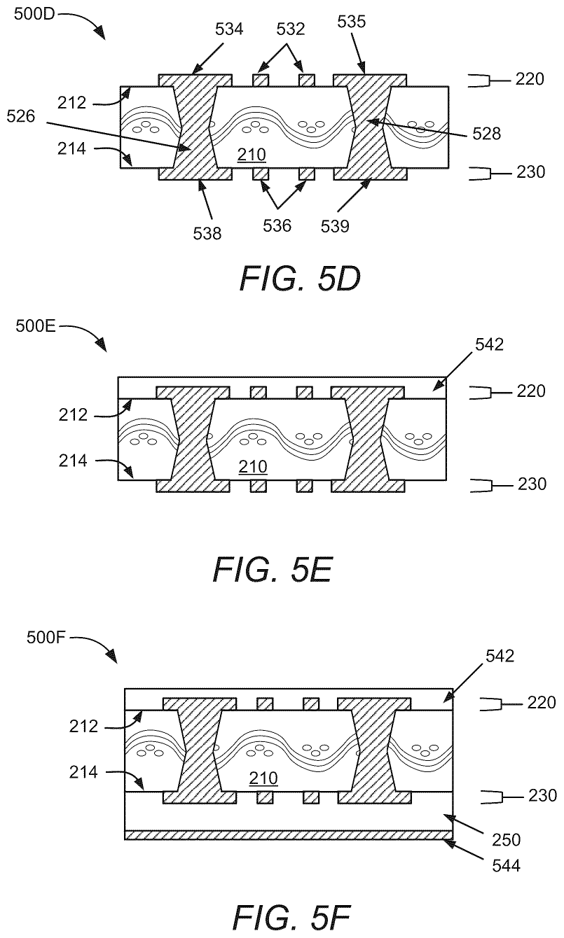

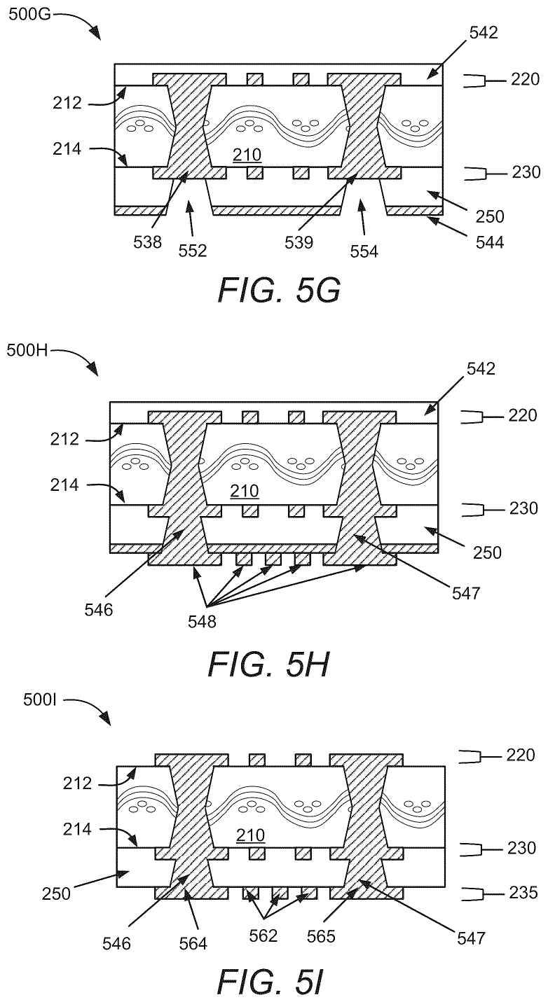

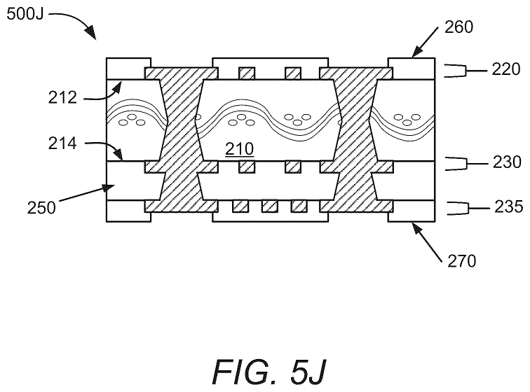

FIGS. 5A-5J illustrate structures at various stages of manufacturing an interposer substrate for an IC package, such as the interposer substrate example 300A in FIG. 3A as a non-limiting example, according to aspects of the disclosure. In some aspects, FIGS. 5A-5J illustrate a manufacturing process that may be usable for manufacturing any of the interposer substrate examples depicted in FIGS. 3A-3E. The components illustrated in FIGS. 5A-5J that are the same or similar to those of FIG. 3A are given the same reference numbers, and the detailed description thereof may be omitted.

As shown in FIG. 5A, a structure 500A which includes a core layer 210, a first conductive layer 512 on a first surface 212 of the core layer 210, and a second conductive layer 514 on a second surface 214 of the core layer 210 is provided. In some aspects, the core layer 210 may include a dielectric material with reinforcement components (e.g., fiber glass sheets) embedded therein. In some aspects, the first conductive layer 512 and the second conductive layer 514 may include a conductive material, such as copper. In some aspects, the core layer 310 may have a thickness ranging from 40 μm to 1000 μm. In some aspects, the structure 500A may correspond to a copper clad laminate (CCL) board.

As shown in FIG. 5B, a structure 500B is formed based on forming one or more openings 516 and 518 through the structure 500A. In some aspects, the openings 516 and 518 may be formed based on mechanical drilling or laser drilling (e.g., by using a CO₂ laser).

As shown in FIG. 5C, a structure 500C is formed based on the structure 500B by patterning the first conductive layer 512 to form a first patterned conductive layer, patterning the second conductive layer 514 to form a second patterned conductive layer, and performing a plating process to fill the openings 516 and 518 to form the one or more via structures 526 and 528, to increase the thickness of the first patterned conductive layer to form the patterned conductive structures 522, and to increase the thickness of the second patterned conductive layer to form the patterned conductive structures 524. In some aspects, the via structures 526 and 528, the patterned conductive structures 522, and patterned conductive structures 524 may include a conductive material such as copper.

As shown in FIG. 5D, a structure 500D is formed based on the structure 500C by etching excessive conductive materials after the plating process to form a first metallization layer 220 on the first surface 212 of the core layer 210 and to form a second metallization layer 230 on the second surface 214 of the core layer 210. In some aspects, the first metallization layer 220 may include one or more trace structures 532 and one or more pad structures 534 and 535. In some aspects, the second metallization layer 230 may include one or more trace structures 536 and one or more pad structures 538 and 539. In some aspects, the via structure 526 may electrically connect the pad structure 534 to the pad structure 538; and electrically connect the pad structure 535 to the pad structure 539.

As shown in FIG. 5E, a structure 500E is formed based on the structure 500D by laminating a dry film resist layer 542 on the first metallization layer 220, where the dry film resist layer 542 may cover the first surface 212 and the conductive structures of the first metallization layer 220.

As shown in FIG. 5F, a structure 500F is formed based on the structure 500E by laminating a dielectric layer 250 on the second metallization layer 230 and a third conductive layer 544 on the dielectric layer 250. In some aspects, the dielectric layer 250 may have a thickness ranging from 20 μm to 70 μm. In some aspects, the dielectric layer 250 and the third conductive layer 544 may be based on a resin coated copper layer that is available as a pre-manufactured component. In some aspects, the dielectric layer 250 and the third conductive layer 544 may be formed based on attaching the resin coated copper layer to the second surface 214 of the core layer 210 and the second metallization layer 230. In some aspects, the second dielectric layer 250 may include resin in an uncured or not-fully-cured state at the stage attaching the resin coated copper layer to the second surface 214 of the core layer 210 and the second metallization layer 230 and may be subsequently cured to complete the structure 500F.

As shown in FIG. 5G, a structure 500G is formed based on forming one or more openings 552 and 554 through the dielectric layer 250 and the third conductive layer 544. In some aspects, the openings 552 and 554 may expose a portion of the pad structures 538 and 539. In some aspects, the openings 552 and 554 may be formed based on mechanical drilling or laser drilling (e.g., by using a CO₂ laser).

As shown in FIG. 5H, a structure 500H is formed based on the structure 500G by patterning the third conductive layer 544 to form a third patterned conductive layer, and performing a plating process to fill the openings 552 and 554 to form the one or more via structures 546 and 547 and to increase the thickness of the third patterned conductive layer to form the patterned conductive structures 548. In some aspects, the via structures 546 and 547 and the patterned conductive structures 548 may include a conductive material such as copper.

As shown in FIG. 5I, a structure 500I is formed based on the structure 500H by etching excessive conductive materials after the plating process to form another metallization layer 235 on the dielectric layer 250 and by removing the dry film resist layer 542. In some aspects, the metallization layer 235 may include one or more trace structures 562 and one or more pad structures 564 and 565. In some aspects, the via structures 546 and 547 may electrically connect various structures of the metallization layer 235 to the second metallization layer 230. In some aspects, the first metallization layer 220 in FIG. 5I and FIG. 3A may correspond to the first metallization structure 320 in FIG. 3E. In some aspects, the second metallization layer 230, the dielectric layer 250, and the metallization layer 235 in FIG. 5I and FIG. 3A may correspond to the second metallization structure 330 in FIG. 3E.

As shown in FIG. 5J, a structure 500J is formed based on the structure 500I by forming a first solder resist layer 260 on the first metallization layer 220 and forming a second solder resist layer 270 on the metallization layer 235. In some aspects, the first solder resist layer 260 may extend between the gaps of conductive structures of the first metallization layer 220 and at least partially disposed on the first surface 212 of the core layer 210. In some aspects, the second solder resist layer 270 may extend between the gaps of conductive structures of the metallization layer 235 and at least partially disposed on a surface of the dielectric layer 250. Compared with the structure 500J, various details of the core layer 210, the first metallization layer 220, the second metallization layer 230, the metallization layer 235, the dielectric layer 250, the first solder resist layer 260, and the second solder resist layer 270 may have been omitted.

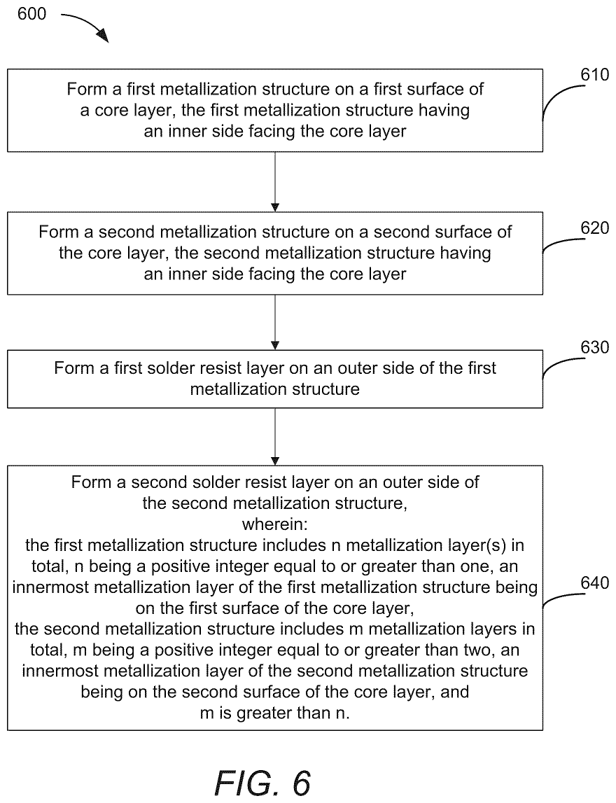

FIG. 6 illustrates a method 600 for manufacturing an interposer substrate (such as an interposer substrate for an IC package incorporating the features of any of the interposer substrate examples 300A-300E or the structure 500J), according to aspects of the disclosure. In some aspects, FIGS. 5A-5J may depict the interposer substrate at different stages of manufacturing according to the method 600. In some aspects, the structure illustrated in this disclosure may be applicable to an interposer substrate as well as a packaging substrate.

At operation 610, a first metallization structure (e.g., the metallization structure 320) can be formed on a first surface of a core layer (e.g., the core layer 210). In some aspects, the first metallization structure may have an inner side facing the core layer.

In some aspects, the forming the first metallization structure may include forming a first metallization layer (e.g., the metallization layer 220) based on a first conductive layer (e.g., the first conductive layer 512) of a CCL board (e.g., the structure 500A). In some aspects, the first metallization layer may be the innermost metallization layer of the first metallization structure on the first surface of the core layer. In some aspects, the CCL board may include the first conductive layer, a second conductive layer, and the core layer between the first conductive layer and the second conductive layer. In some aspects, the first metallization structure may be formed at least based on the first conductive layer.

At operation 620, a second metallization structure (e.g., the metallization structure 330) can be formed on a second surface of the core layer. In some aspects, the second metallization structure may have an inner side facing the core layer. In some aspects, the second metallization structure may be formed at least based on the second conductive layer.

In some aspects, the forming the second metallization structure may include forming a second metallization layer (e.g., the metallization layer 230) based on the second conductive layer (e.g., the second conductive layer 514) of the CCL board (e.g., the structure 500A). In some aspects, the second metallization layer may be the innermost metallization layer of the second metallization structure on the second surface of the core layer. In some aspects, the forming the second metallization structure may include forming a dielectric layer (e.g., the dielectric layer 250) on the second metallization layer, and forming a third metallization layer (e.g., the metallization layer 235) on the dielectric layer such that the dielectric layer is between the second metallization layer and the third metallization layer.

In some aspects, the core layer may have a thickness ranging from 40 μm to 1000 μm. In some aspects, the dielectric layer of the second metallization structure may have a thickness ranging from 20 μm to 70 μm.

In some aspects, the forming the dielectric layer may include laminating, on the second metallization layer, a layer of dielectric material with pre-impregnated reinforcement components embedded therein.

In some aspects, the second metallization structure may include one or more via structures between the second metallization layer and the third metallization layer. In some aspects, the forming the second metallization structure may further include forming one or more openings in the dielectric layer; forming a third conductive layer on the dielectric layer; patterning the third conductive layer to form a patterned conductive layer; performing a plating process to fill the one or more openings to form the one or more via structures (e.g., the via structures 546 and 547) and to increase a thickness of the patterned conductive layer; and etching excessive conductive materials after the plating process to form the third metallization layer.

In some aspects, the first metallization layer may include first conductive patterns configured to carry a first supply power or a first signal of the IC package. In some aspects, the second metallization layer may include second conductive patterns configured to carry a second supply power or a ground level (e.g., for power or signal returning paths and/or shielding) of the IC package. In some aspects, the third metallization layer may include third conductive patterns configured to carry a second signal or the first supply power of the IC package.

At operation 630, a first solder resist layer (e.g., the solder resist layer 260 or 340) may be formed on an outer side of the first metallization structure. At operation 640, a second solder resist layer (e.g., the solder resist layer 270 or 350) may be formed on an outer side of the second metallization structure.

In some aspects, the first metallization structure may include n metallization layer(s) in total, where n may be a positive integer equal to or greater than one. In some aspects, an innermost metallization layer of the first metallization structure may be on the first surface of the core layer. In some aspects, the second metallization structure may include m metallization layers in total, where m may be a positive integer equal to or greater than two. In some aspects, an innermost metallization layer of the second metallization structure may be on the second surface of the core layer. In some aspects, m is greater than n. In some aspects, m may be two and n may be one.

In some aspects, the forming the first metallization structure may include forming (n−1) dielectric layers disposed between respective pairs of adjacent metallization layers of the first metallization structure. In some aspects, the forming the second metallization structure may include forming (m−1) dielectric layers disposed between respective pairs of adjacent metallization layers of the second metallization structure. In some aspects, each one of the dielectric layers of the first metallization structure and of the second metallization structure may have a thickness ranging from 20 μm to 70 μm. In some aspects, each one of the dielectric layers of the first metallization structure and of the second metallization structure may include a dielectric material with pre-impregnated reinforcement components embedded therein.

In some aspects, the method 600 may further include forming an outer dielectric layer (e.g., the outer dielectric layer 302, 306, or 360) that is between the first metallization structure and the first solder resist layer. In some aspects, the outer dielectric layer may be free from having glass fibers.

A technical advantage of the method 600 corresponds to manufacturing an interposer substrate that includes an offset core layer, which corresponds to having different numbers of metallization layers on respective sides of the core layer. Accordingly, a cored interposer based on the interposer substrate described herein with an odd number of metallization layers may be formed such that the proper rigidity for an IC package may be maintained and the target SIPI performance may be achieved, while the thickness of the interposer may be well managed or reduced.

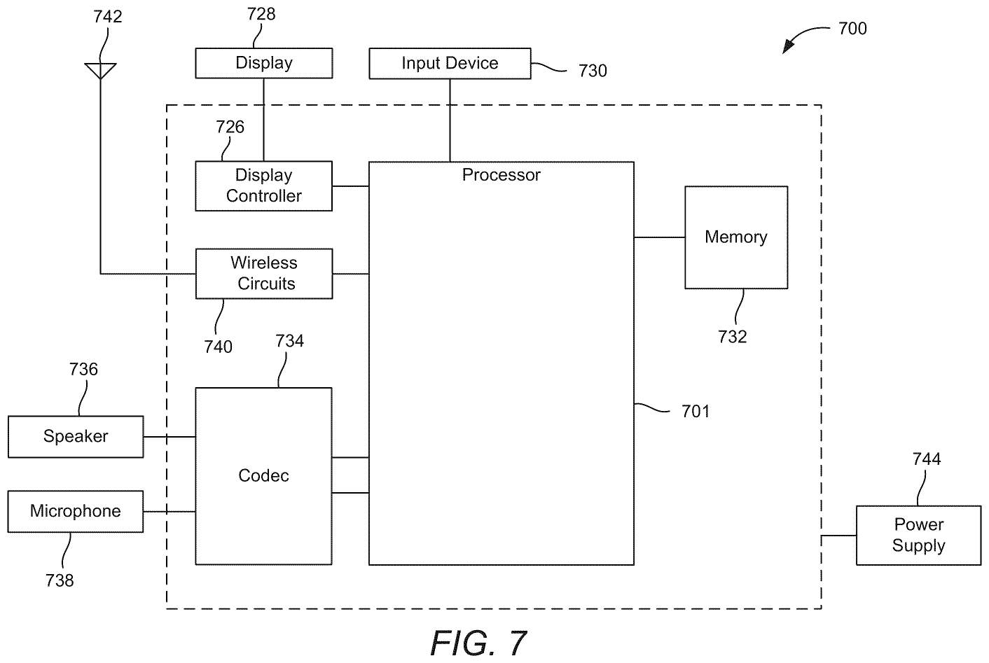

FIG. 7 illustrates a mobile device 700, according to aspects of the disclosure. In some aspects, the mobile device 700 may be implemented by including one or more IC devices including the interposer substrates as disclosed herein.

In some aspects, mobile device 700 may be configured as a wireless communication device. As shown, mobile device 700 includes processor 701. Processor 701 may be communicatively coupled to memory 732 over a link, which may be a die-to-die or chip-to-chip link. Mobile device 700 also includes display 728 and display controller 726, with display controller 726 coupled to processor 701 and to display 728. The mobile device 700 may include input device 730 (e.g., physical, or virtual keyboard), power supply 744 (e.g., battery), speaker 736, microphone 738, and wireless antenna 742. In some aspects, the power supply 744 may directly or indirectly provide the supply voltage for operating some or all of the components of the mobile device 700.

In some aspects, FIG. 7 may include coder/decoder (CODEC) 734 (e.g., an audio and/or voice CODEC) coupled to processor 701; speaker 736 and microphone 738 coupled to CODEC 734; and wireless circuits 740 (which may include a modem, RF circuitry, filters, etc.) coupled to wireless antenna 742 and to processor 701.

In some aspects, one or more of processor 701 (e.g., SoCs, application processor (AP)), display controller 726, memory 732, CODEC 734, and wireless circuits 740 (e.g., baseband interface) including IC devices that are packaged as IC packages and including interposer substrates according to the various aspects described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

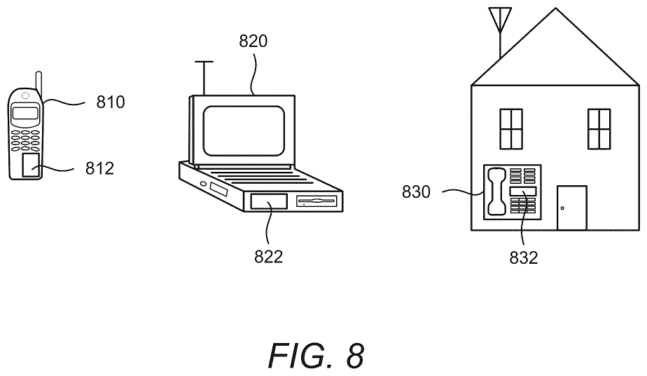

FIG. 8 illustrates various electronic devices 810, 820, and 830 that may incorporate IC devices 812, 822, and 832, which may be packaged as IC packages having interposer substrates described herein, according to aspects of the disclosure.

For example, a mobile phone device 810, a laptop computer device 820, and a fixed location terminal device 830 may each be considered generally user equipment (UE) and may include one or more IC devices, such as IC devices 812, 822, and 832, and a power supply to provide the supply voltages to power the IC devices. The IC devices 812, 822, and 832 may be, for example, correspond to an IC device packaged as an IC package having an interposer substrate manufactured based on the examples described above with reference to FIGS. 3A-3E and 5A-5J.

The devices 810, 820, and 830 illustrated in FIG. 8 are merely non-limiting examples. Other electronic devices may also feature the IC devices including interposer substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature, or function or incorporated in several components, processes, or functions. Additional elements, components, processes, and/or functions may also be added without departing from the disclosure. In some implementations, FIGS. 1-8 and the corresponding description may be used to manufacture, create, provide, and/or produce integrated devices. In some implementations, a device may include a die, an integrated device, a dic package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An interposer substrate for an integrated circuit (IC) package, comprising: a core layer having a first surface and a second surface; a first metallization structure on the first surface of the core layer, the first metallization structure having an inner side facing the core layer; a second metallization structure on the second surface of the core layer, the second metallization structure having an inner side facing the core layer; a first solder resist layer on an outer side of the first metallization structure; and a second solder resist layer on an outer side of the second metallization structure, wherein: the first metallization structure includes n metallization layer(s) in total, n being a positive integer equal to or greater than one, an innermost metallization layer of the first metallization structure being on the first surface of the core layer, the second metallization structure includes m metallization layers in total, m being a positive integer equal to or greater than two, an innermost metallization layer of the second metallization structure being on the second surface of the core layer, and m is greater than n.

Clause 2. The interposer substrate of clause 1, wherein: the core layer has a thickness ranging from 40 micrometers (μm) to 1000 μm.

Clause 3. The interposer substrate of any of clauses 1 to 2, further comprising: an outer dielectric layer between the first metallization structure and the first solder resist layer.

Clause 4. The interposer substrate of clause 3, wherein: the outer dielectric layer is free from having glass fibers.

Clause 5. The interposer substrate of any of clauses 1 to 4, wherein: based on n being greater than one, the first metallization structure further includes (n−1) dielectric layers disposed between respective pairs of adjacent metallization layers of the first metallization structure, and the second metallization structure further includes (m−1) dielectric layers disposed between respective pairs of adjacent metallization layers of the second metallization structure.

Clause 6. The interposer substrate of clause 5, wherein: the core layer has a thickness ranging from 40 micrometers (μm) to 1000 μm, and each one of the dielectric layers of the first metallization structure and of the second metallization structure has a thickness ranging from 20 μm to 70 μm.

Clause 7. The interposer substrate of any of clauses 5 to 6, wherein: each one of the dielectric layers of the first metallization structure and of the second metallization structure comprises a dielectric material with pre-impregnated reinforcement components embedded therein.

Clause 8. The interposer substrate of any of clauses 1 to 4, wherein, based on n being one and m being two: the first metallization structure includes a first metallization layer that is the innermost metallization layer of the first metallization structure, the second metallization structure includes a second metallization layer that is the innermost metallization layer of the second metallization structure, and the second metallization structure further includes a third metallization layer and a dielectric layer between the second metallization layer and the third metallization layer.

Clause 9. The interposer substrate of clause 8, wherein: the first metallization layer includes first conductive patterns configured to carry a first supply power or a first signal of the IC package, the second metallization layer includes second conductive patterns configured to carry a second supply power or a ground level of the IC package, and the third metallization layer includes third conductive patterns configured to carry a second signal or the first supply power of the IC package.

Clause 10. The interposer substrate of any of clauses 8 to 9, wherein: the core layer has a thickness ranging from 40 micrometers (μm) to 1000 μm, and the dielectric layer of the second metallization structure has a thickness ranging from 20 μm to 70 μm.

Clause 11. A method of manufacturing an interposer substrate for integrated circuit (IC) packaging, comprising: forming a first metallization structure on a first surface of a core layer, the first metallization structure having an inner side facing the core layer; forming a second metallization structure on a second surface of the core layer, the second metallization structure having an inner side facing the core layer; forming a first solder resist layer on an outer side of the first metallization structure; and forming a second solder resist layer on an outer side of the second metallization structure, wherein: the first metallization structure includes n metallization layer(s) in total, n being a positive integer equal to or greater than one, an innermost metallization layer of the first metallization structure being on the first surface of the core layer, the second metallization structure includes m metallization layers in total, m being a positive integer equal to or greater than two, an innermost metallization layer of the second metallization structure being on the second surface of the core layer, and m is greater than n.

Clause 12. The method of clause 11, wherein: the forming the first metallization structure comprises: forming a first metallization layer based on a first conductive layer of a copper clad laminate (CCL) board, the first metallization layer being the innermost metallization layer of the first metallization structure on the first surface of the core layer, the CCL board includes the first conductive layer, a second conductive layer, and the core layer between the first conductive layer and the second conductive layer, and the forming the second metallization structure comprises: forming a second metallization layer based on the second conductive layer of the CCL board, the second metallization layer being the innermost metallization layer of the second metallization structure on the second surface of the core layer; forming a dielectric layer on the second metallization layer; and forming a third metallization layer on the dielectric layer such that the dielectric layer is between the second metallization layer and the third metallization layer.

Clause 13. The method of clause 12, wherein: the core layer has a thickness ranging from 40 micrometers (μm) to 1000 μm, and the dielectric layer of the second metallization structure has a thickness ranging from 20 μm to 70 μm.

Clause 14. The method of any of clauses 12 to 13, wherein: the forming the dielectric layer comprises laminating, on the second metallization layer, a layer of dielectric material with pre-impregnated reinforcement components embedded therein.

Clause 15. The method of any of clauses 12 to 14, wherein: the second metallization structure comprises one or more via structures between the second metallization layer and the third metallization layer, and the forming the second metallization structure comprises: forming one or more openings in the dielectric layer; forming a third conductive layer on the dielectric layer; patterning the third conductive layer to form a patterned conductive layer; performing a plating process to fill the one or more openings to form the one or more via structures and to increase a thickness of the patterned conductive layer; and etching excessive conductive materials after the plating process to form the third metallization layer.

Clause 16. The method of any of clauses 12 to 15, wherein m is two and n is one.

Clause 17. The method of any of clauses 11 to 16, further comprising: forming an outer dielectric layer that is between the first metallization structure and the first solder resist layer, wherein the outer dielectric layer is free from having glass fibers.

Clause 18. The method of any of clauses 11 to 17, further comprising, based on n being greater than one: forming (n−1) dielectric layers disposed between respective pairs of adjacent metallization layers of the first metallization structure; and forming (m−1) dielectric layers disposed between respective pairs of adjacent metallization layers of the second metallization structure.

Clause 19. The method of clause 18, wherein: the core layer has a thickness ranging from 40 micrometers (μm) to 1000 μm, and each one of the dielectric layers of the first metallization structure and of the second metallization structure has a thickness ranging from 20 μm to 70 μm.

Clause 20. The method of any of clauses 18 to 19, wherein: each one of the dielectric layers of the first metallization structure and of the second metallization structure comprises a dielectric material with pre-impregnated reinforcement components embedded therein.

Clause 21. The method of any of clauses 12 to 20, wherein: the first metallization layer includes first conductive patterns configured to carry a first supply power or a first signal of the IC package, the second metallization layer includes second conductive patterns configured to carry a second supply power or a ground level of the IC package, and the third metallization layer includes third conductive patterns configured to carry a second signal or the first supply power of the IC package.

Clause 22. An electronic device, comprising: an integrated circuit (IC) package including an interposer substrate, wherein the interposer substrate comprises: a core layer having a first surface and a second surface; a first metallization structure on the first surface of the core layer, the first metallization structure having an inner side facing the core layer; a second metallization structure on the second surface of the core layer, the second metallization structure having an inner side facing the core layer; a first solder resist layer on an outer side of the first metallization structure; and a second solder resist layer on an outer side of the second metallization structure, wherein: the first metallization structure includes n metallization layer(s) in total, n being a positive integer equal to or greater than one, an innermost metallization layer of the first metallization structure being on the first surface of the core layer, the second metallization structure includes m metallization layers in total, m being a positive integer equal to or greater than two, an innermost metallization layer of the second metallization structure being on the second surface of the core layer, and m is greater than n.

Clause 23. The electronic device of clause 22, wherein the IC package further comprises: a first IC disposed over and electrically connected to the first metallization structure; and a second IC disposed under and electrically connected to the second metallization structure.

Clause 24. The electronic device of any of clauses 22 to 23: based on n being greater than one, the first metallization structure further includes (n−1) dielectric layers disposed between respective pairs of adjacent metallization layers of the first metallization structure, and the second metallization structure further includes (m−1) dielectric layers disposed between respective pairs of adjacent metallization layers of the second metallization structure.

Clause 25. The electronic device of clause 24, wherein: the core layer has a thickness ranging from 40 micrometers (μm) to 1000 μm, and each one of the dielectric layers of the first metallization structure and of the second metallization structure has a thickness ranging from 20 μm to 70 μm.

Clause 26. The electronic device of any of clauses 24 to 25, wherein: each one of the dielectric layers of the first metallization structure and of the second metallization structure comprises a dielectric material with pre-impregnated reinforcement components embedded therein.

Clause 27. The electronic device of any of clauses 22 to 26, wherein: the first metallization structure includes a first metallization layer that is the innermost metallization layer of the first metallization structure, the second metallization structure includes a second metallization layer that is the innermost metallization layer of the second metallization structure, and the second metallization structure further includes a third metallization layer and a dielectric layer between the second metallization layer and the third metallization layer.

Clause 28. The electronic device of clause 27, wherein: the first metallization layer includes first conductive patterns configured to carry a first supply power or a first signal of the IC package, the second metallization layer includes second conductive patterns configured to carry a second supply power or a ground level of the IC package, and the third metallization layer includes third conductive patterns configured to carry a second signal or the first supply power of the IC package.

Clause 29. The electronic device of any of clauses 27 to 28, wherein: the core layer has a thickness ranging from 40 micrometers (μm) to 1000 μm, and the dielectric layer of the second metallization structure has a thickness ranging from 20 μm to 70 μm.

Clause 30. The electronic device of any of clauses 22 to 29, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An interposer substrate for an integrated circuit (IC) package, comprising:
a core layer having a first surface and a second surface;
a first metallization structure on the first surface of the core layer, the first metallization structure having an inner side facing the core layer;
a second metallization structure on the second surface of the core layer, the second metallization structure having an inner side facing the core layer;
a first solder resist layer on an outer side of the first metallization structure; and
a second solder resist layer on an outer side of the second metallization structure,
wherein:
the first metallization structure includes n metallization layer(s) in total, n being a positive integer equal to or greater than one, an innermost metallization layer of the first metallization structure being on the first surface of the core layer,
the second metallization structure includes m metallization layers in total, m being a positive integer equal to or greater than two, an innermost metallization layer of the second metallization structure being on the second surface of the core layer, and
m is greater than n.

2. The interposer substrate of claim 1, wherein:
the core layer has a thickness ranging from 40 micrometers (μm) to 1000 μm.

3. The interposer substrate of claim 1, further comprising:
an outer dielectric layer between the first metallization structure and the first solder resist layer.

4. The interposer substrate of claim 3, wherein:
the outer dielectric layer is free from having glass fibers.

5. The interposer substrate of claim 1, wherein:
based on n being greater than one, the first metallization structure further includes (n−1) dielectric layers disposed between respective pairs of adjacent metallization layers of the first metallization structure, and
the second metallization structure further includes (m−1) dielectric layers disposed between respective pairs of adjacent metallization layers of the second metallization structure.

6. The interposer substrate of claim 5, wherein:
the core layer has a thickness ranging from 40 micrometers (μm) to 1000 μm, and
each one of the dielectric layers of the first metallization structure and of the second metallization structure has a thickness ranging from 20 μm to 70 μm.

7. The interposer substrate of claim 5, wherein:
each one of the dielectric layers of the first metallization structure and of the second metallization structure comprises a dielectric material with pre-impregnated reinforcement components embedded therein.

8. The interposer substrate of claim 1, wherein, based on n being one and m being two:
the first metallization structure includes a first metallization layer that is the innermost metallization layer of the first metallization structure,
the second metallization structure includes a second metallization layer that is the innermost metallization layer of the second metallization structure, and
the second metallization structure further includes a third metallization layer and a dielectric layer between the second metallization layer and the third metallization layer.

9. The interposer substrate of claim 8, wherein:
the first metallization layer includes first conductive patterns configured to carry a first supply power or a first signal of the IC package,
the second metallization layer includes second conductive patterns configured to carry a second supply power or a ground level of the IC package, and
the third metallization layer includes third conductive patterns configured to carry a second signal or the first supply power of the IC package.

10. The interposer substrate of claim 8, wherein:
the core layer has a thickness ranging from 40 micrometers (μm) to 1000 μm, and
the dielectric layer of the second metallization structure has a thickness ranging from 20 μm to 70 μm.

11. A method of manufacturing an interposer substrate for integrated circuit (IC) packaging, comprising:
forming a first metallization structure on a first surface of a core layer, the first metallization structure having an inner side facing the core layer;
forming a second metallization structure on a second surface of the core layer, the second metallization structure having an inner side facing the core layer;
forming a first solder resist layer on an outer side of the first metallization structure; and
forming a second solder resist layer on an outer side of the second metallization structure,
wherein:
the first metallization structure includes n metallization layer(s) in total, n being a positive integer equal to or greater than one, an innermost metallization layer of the first metallization structure being on the first surface of the core layer,
the second metallization structure includes m metallization layers in total, m being a positive integer equal to or greater than two, an innermost metallization layer of the second metallization structure being on the second surface of the core layer, and
m is greater than n.

12. The method of claim 11, wherein:
the forming the first metallization structure comprises:
forming a first metallization layer based on a first conductive layer of a copper clad laminate (CCL) board, the first metallization layer being the innermost metallization layer of the first metallization structure on the first surface of the core layer,
the CCL board includes the first conductive layer, a second conductive layer, and the core layer between the first conductive layer and the second conductive layer, and
the forming the second metallization structure comprises:
forming a second metallization layer based on the second conductive layer of the CCL board, the second metallization layer being the innermost metallization layer of the second metallization structure on the second surface of the core layer;
forming a dielectric layer on the second metallization layer; and
forming a third metallization layer on the dielectric layer such that the dielectric layer is between the second metallization layer and the third metallization layer.

13. The method of claim 12, wherein:
the core layer has a thickness ranging from 40 micrometers (μm) to 1000 μm, and
the dielectric layer of the second metallization structure has a thickness ranging from 20 μm to 70 μm.

14. The method of claim 12, wherein:
the forming the dielectric layer comprises laminating, on the second metallization layer, a layer of dielectric material with pre-impregnated reinforcement components embedded therein.

15. The method of claim 12, wherein:
the second metallization structure comprises one or more via structures between the second metallization layer and the third metallization layer, and
the forming the second metallization structure comprises:
forming one or more openings in the dielectric layer;
forming a third conductive layer on the dielectric layer;
patterning the third conductive layer to form a patterned conductive layer;
performing a plating process to fill the one or more openings to form the one or more via structures and to increase a thickness of the patterned conductive layer; and
etching excessive conductive materials after the plating process to form the third metallization layer.

16. The method of claim 12, wherein m is two and n is one.

17. The method of claim 11, further comprising:
forming an outer dielectric layer that is between the first metallization structure and the first solder resist layer,
wherein the outer dielectric layer is free from having glass fibers.

18. The method of claim 11, further comprising, based on n being greater than one:
forming (n−1) dielectric layers disposed between respective pairs of adjacent metallization layers of the first metallization structure; and
forming (m−1) dielectric layers disposed between respective pairs of adjacent metallization layers of the second metallization structure.

19. The method of claim 18, wherein:
the core layer has a thickness ranging from 40 micrometers (μm) to 1000 μm, and
each one of the dielectric layers of the first metallization structure and of the second metallization structure has a thickness ranging from 20 μm to 70 μm.

20. The method of claim 18, wherein:
each one of the dielectric layers of the first metallization structure and of the second metallization structure comprises a dielectric material with pre-impregnated reinforcement components embedded therein.

21. The method of claim 12, wherein:
the first metallization layer includes first conductive patterns configured to carry a first supply power or a first signal of the IC package,
the second metallization layer includes second conductive patterns configured to carry a second supply power or a ground level of the IC package, and
the third metallization layer includes third conductive patterns configured to carry a second signal or the first supply power of the IC package.

22. An electronic device, comprising:
an integrated circuit (IC) package including an interposer substrate, wherein the interposer substrate comprises:
a core layer having a first surface and a second surface;
a first metallization structure on the first surface of the core layer, the first metallization structure having an inner side facing the core layer;
a second metallization structure on the second surface of the core layer,
the second metallization structure having an inner side facing the core layer;
a first solder resist layer on an outer side of the first metallization structure; and
a second solder resist layer on an outer side of the second metallization structure,
wherein:
the first metallization structure includes n metallization layer(s) in total, n being a positive integer equal to or greater than one, an innermost metallization layer of the first metallization structure being on the first surface of the core layer,
the second metallization structure includes m metallization layers in total, m being a positive integer equal to or greater than two, an innermost metallization layer of the second metallization structure being on the second surface of the core layer, and
m is greater than n.

23. The electronic device of claim 22, wherein the IC package further comprises:
a first IC disposed over and electrically connected to the first metallization structure; and
a second IC disposed under and electrically connected to the second metallization structure.

24. The electronic device of claim 22:
based on n being greater than one, the first metallization structure further includes (n−1) dielectric layers disposed between respective pairs of adjacent metallization layers of the first metallization structure, and
the second metallization structure further includes (m−1) dielectric layers disposed between respective pairs of adjacent metallization layers of the second metallization structure.

25. The electronic device of claim 24, wherein:
the core layer has a thickness ranging from 40 micrometers (μm) to 1000 μm, and
each one of the dielectric layers of the first metallization structure and of the second metallization structure has a thickness ranging from 20 μm to 70 μm.

26. The electronic device of claim 24, wherein:
each one of the dielectric layers of the first metallization structure and of the second metallization structure comprises a dielectric material with pre-impregnated reinforcement components embedded therein.

27. The electronic device of claim 22, wherein:
the first metallization structure includes a first metallization layer that is the innermost metallization layer of the first metallization structure,
the second metallization structure includes a second metallization layer that is the innermost metallization layer of the second metallization structure, and
the second metallization structure further includes a third metallization layer and a dielectric layer between the second metallization layer and the third metallization layer.

28. The electronic device of claim 27, wherein:
the first metallization layer includes first conductive patterns configured to carry a first supply power or a first signal of the IC package,
the second metallization layer includes second conductive patterns configured to carry a second supply power or a ground level of the IC package, and
the third metallization layer includes third conductive patterns configured to carry a second signal or the first supply power of the IC package.

29. The electronic device of claim 27, wherein:
the core layer has a thickness ranging from 40 micrometers (μm) to 1000 μm, and
the dielectric layer of the second metallization structure has a thickness ranging from 20 μm to 70 μm.

30. The electronic device of claim 22, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
